(19) United States
(12) Patent Application Publication
(10) Pub. No.: US 2008/0171412 A1
(43) Pub. Date: Jul. 17, 2008

(54) FABRICATION METHODS FOR MOS DEVICE AND CMOS DEVICE

(75) Inventors: Po-Lun Cheng, Kaohsiung County (TW); Che-Hung Liu, Tainan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/622,830

(22) Filed: Jan. 12, 2007

(51) Int. Cl. H01L 21/8238; H01L 21/336

(52) U.S. Cl. 438/218; 438/285; 257/E21.634; 257/E21.403

(57) ABSTRACT

Fabrication methods for a MOS device and a CMOS device are provided. A substrate is provided with a gate structure formed on the substrate, a lightly-doped drain (LDD) region formed near sides of the gate structure in the substrate and a spacer wall formed on sidewalls of the gate structure and covering a part of the LDD region. A protection layer is formed for covering the gate structure, the LDD region and the spacer wall. A part of the protection layer is removed. Another part of the protection layer on the gate structure and the spacer wall is reserved. A part of the surface of the substrate is exposed. The exposed surface of the substrate is removed for forming a trench. A pre-clean step, including an oxygen plasma process, is performed on the bottom of the trench. An epitaxy material layer is formed in the trench.

### BACKGROUND OF THE INVENTION

1. Field of Invention

The present invention relates to a fabrication method an integrated circuit (IC) device, and more particularly to fabrication methods for a Metal-Oxide-Semiconductor (MOS) device and a Complementary Metal-Oxide-Semiconductor (CMOS) device.

2. Description of Related Art

Now, a SiGe process is used in implementing source/drain regions in a MOS transistor for raising mobility of electrons and holes and also the performance of the MOS transistor.

In general, in the SiGe process for implementing MOS transistor, a gate structure, a lightly-doped drain (LDD) region and a spacer layer are formed over a substrate and then an oxide layer is formed over the substrate. A part of the oxide layer is removed for exposing a part of the surface of the substrate, but parts of the oxide layer over the gate structure and the spacer layer are remained for protecting the gate structure and the spacer layer. Then, the exposed substrate is removed for forming a trench. A SiGe alloy metal layer is filled into the trench and then a MOS transistor is made.

Before the SiGe alloy metal layer is filled, a pre-clean step is performed on the trench for cleaning impurities or native oxide layer on the bottom of the trench to ensure the formation quality of the subsequent SiGe alloy metal layer. In the pre-clean step, a 90-second clean by diluted hydrofluoric acid (DHF) solution (HF: H₂O=1:200), then a O₃ solution clean and another 90-second clean by DHF are performed.

However, in the DHF-O₃-DHF pre-clean, when in cleaning impurities or native oxide layer on the bottom of the trench, parts of the oxide layer over the gate structure and the spacer layer would be error removed and the gate structure is unintentionally exposed. Therefore, in the filling of the SiGe alloy metal layer, the SiGe alloy metal would be disposed on the exposed gate structure. This is referred as “poly bump”, which may severely downgrade the reliability and performance of the resultant MOS transistor.

### SUMMARY OF THE INVENTION

The present invention is to provide a fabrication method for a MOS device and a CMOS device for preventing poly bump disadvantage and improving reliability and performance of the resultant devices.

In the present invention, a method for fabricating a MOS device is provided. In the fabrication method, a substrate is provided with a gate structure formed on the substrate, a lightly-doped drain region formed near sides of the gate structure in the substrate and a spacer wall formed on sidewalls of the gate structure and covering a part of the lightly-doped drain region. A protection layer is formed on the substrate for covering the gate structure, the lightly-doped drain region and the spacer wall. An anisotropic etching is performed for removing a part of the protection layer, reserving another part of the protection layer on the gate structure and the spacer wall, and exposing a part of the surface of the substrate. The exposed surface of the substrate is removed for forming a trench in the substrate. A pre-clean step is performed on the bottom of the trench, the pre-clean step including an oxygen plasma process. An epitaxy material layer is formed in the trench.

In the above fabrication method, the oxygen plasma process has a power condition between 10 W˜2000 W. The oxygen plasma process has a temperature condition between 300° C.˜500° C. A gas source used in the oxygen plasma process includes O₂, NO or N₂O. A secondary gas source used in the oxygen plasma process includes H₂, NH₃ or D₂.

In the above fabrication method, the pre-clean step further includes a DHF clean step. A duration for the DHF clean step is between 60 seconds˜180 seconds, a temperature condition for the DHF clean step is room temperature (25 degree C.), and a concentration of a HF solution used in the DHF clean step is a volume percent of 0.5.

The above fabrication method further includes a pre-bake step after the pre-clean step.

In the above fabrication method, if the MOS device is a P-type MOS transistor, the epitaxy material layer is a SiGe alloy metal layer.

In the above fabrication method, if the MOS device is an N-type MOS transistor, the epitaxy material layer is a SiC layer.

In the present invention, another method for fabricating a MOS device is provided. In this method, a substrate is provided with a gate structure formed on the substrate, a lightly-doped drain region formed near sides of the gate structure in the substrate and a spacer wall formed on sidewalls of the gate structure and covering apart of the lightly-doped drain region. A protection layer is formed on the substrate for covering the gate structure, the lightly-doped drain region and the spacer wall. An anisotropic etching is performed for removing a part of the protection layer, reserving another part of the protection layer on the gate structure and the spacer wall, and exposing a part of the surface of the substrate. The exposed surface of the substrate is removed and another part of the protection layer on the gate structure and a part of the gate structure is removed for forming a trench in the substrate. A pre-clean step is performed on the bottom of the trench, the pre-clean step including an oxygen plasma process. An epitaxy material layer is formed in the trench.

In the above fabrication method, the oxygen plasma process has a power condition between 10 W˜2000 W. The oxygen plasma process has a temperature condition between 300° C.˜500° C. A gas source used in the oxygen plasma process includes O₂, NO or N₂O. A secondary gas source used in the oxygen plasma process includes H₂, NH₃ or D₂.

In the above fabrication method, the pre-clean step further includes a DHF clean step. A duration for the DHF clean step is between 60 seconds˜180 seconds, a temperature condition for the DHF clean step is room temperature (25 degree C.), and a concentration of a HF solution used in the DHF clean step is a volume percent of 0.5.

The above fabrication method further comprises a pre-bake step after the pre-clean step.

In the above fabrication method, if the MOS device is a P-type MOS transistor, the epitaxy material layer is a SiGe alloy metal layer.

The present invention provides a method for fabricating a CMOS device. A substrate is provided with first and second active regions, the first and second active regions being isolated by an isolation structure, a first gate structure formed in the first active region of the substrate, a first lightly-doped drain region formed near sides of the first gate structure in the substrate and a first spacer wall formed on sidewalls of the first gate structure and covering a part of the first lightly-doped drain region; a second gate structure formed in the second active region of the substrate, a second lightly-doped drain region formed near sides of the second gate structure in the substrate and a second spacer wall formed on sidewalls of the second gate structure and covering a part of the second lightly-doped drain region. A protection layer is formed on the substrate for covering the substrate. A part of the protection layer in the first active region is removed. Another part of the protection layer on the first gate structure and the first spacer wall is reserved. A part of the surface of the substrate in the first active region is exposed. The exposed surface of the substrate in the first active region is removed for forming a trench. A pre-clean step is performed on the bottom of the trench, the pre-clean step including an oxygen plasma process. An epitaxy material layer is formed in the trench. The protection layer is removed. A heavily doped region is formed near sides of the second spacer wall in the second active region of the substrate.

In the above fabrication method, the oxygen plasma process has a power condition between 10 W˜2000 W. The oxygen plasma process has a temperature condition between 300° C.˜500° C. A gas source used in the oxygen plasma process includes O₂, NO or N₂O. A secondary gas source used in the oxygen plasma process includes H₂, NH₃ or D₂.

In the above fabrication method, the pre-clean step further includes a DHF clean step. A duration for the DHF clean step is between 60 seconds˜180 seconds, a temperature condition for the DHF clean step is room temperature (25 degree C.), and a concentration of a HF solution used in the DHF clean step is a volume percent of 0.5.

The above fabrication method further comprises a pre-bake step after the pre-clean step.

In the above fabrication method, if a MOS device in the first active region is a P-type MOS transistor, the epitaxy material layer is a SiGe alloy metal layer.

In the above fabrication method, if a MOS device in the first active region is an N-type MOS transistor, the epitaxy material layer is a SiC layer.

In the above fabrication method, the step of removing the exposed surface of the substrate in the first active region for forming the trench includes a step of removing a part of the protection layer covering the first gate structure and removing a part of the first gate structure. If a MOS device in the first active region is a P-type MOS transistor, the epitaxy material layer is a SiGe alloy metal layer.

The present invention also provides a method for fabricating a CMOS device. A substrate is provided with first and second active regions, the first and second active regions being isolated by an isolation structure, a first gate structure formed in the first active region of the substrate, a first lightly-doped drain region formed near sides of the first gate structure in the substrate and a first spacer wall formed on sidewalls of the first gate structure and covering a part of the first lightly-doped drain region; a second gate structure formed in the second active region of the substrate, a second lightly-doped drain region formed near sides of the second gate structure in the substrate and a second spacer wall formed on sidewalls of the second gate structure and covering a part of the second lightly-doped drain region. A protection layer is formed on the substrate for covering the substrate. A part of the protection layer is formed in the first active region. Another part of the protection layer on the first gate structure and the first spacer wall is reserved. A part of the surface of the substrate in the first active region is exposed. The exposed surface of the substrate in the first active region is removed for forming a first trench. A pre-clean step is performed on the bottom of the first trench, the pre-clean step including an oxygen plasma process. A first epitaxy material layer is formed in the first trench. A part of the protection layer in the second active region is removed. Another part of the protection layer on the second gate structure and the second spacer wall is reserved. A part of the surface of the substrate in the second active region is exposed. The exposed surface of the substrate in the second active region is removed for forming a second trench. The pre-clean step is performed on the bottom of the second trench. A second epitaxy material layer is formed in the second trench.

In the above fabrication method, the oxygen plasma process has a power condition between 10 W˜2000 W. The oxygen plasma process has a temperature condition between 300° C.˜500° C. A gas source used in the oxygen plasma process includes O₂, NO or N₂O. A secondary gas source used in the oxygen plasma process includes H₂, NH₃ or D₂.

In the above fabrication method, the pre-clean step further includes a DHF clean step. A duration for the DHF clean step is between 60 seconds˜180 seconds, a temperature condition for the DHF clean step is room temperature (25 degree C.), and a concentration of a HF solution used in the DHF clean step is a volume percent of 0.5.

The above fabrication method further comprises a pre-bake step after the pre-clean step.

In the above fabrication method, if a MOS device in the first active region is a P-type MOS transistor, the first epitaxy material layer is a SiGe alloy metal layer; and if a MOS device in the second active region is an N-type MOS transistor, the second epitaxy material layer is a SiC layer.

In the above fabrication method, if a MOS device in the first active region is an N-type MOS transistor, the first epitaxy material layer is a SiC layer; and if a MOS device in the second active region is a P-type MOS transistor, the second epitaxy material layer is a SiGe alloy metal layer.

In the above fabrication method, the step of removing the exposed surface of the substrate in the first active region for forming the first trench includes a step of removing a part of the protection layer covering the first gate structure and removing a part of the first gate structure. If a MOS device in the first active region is a P-type MOS transistor, the first epitaxy material layer is a SiGe alloy metal layer and if a MOS device in the second active region is an N-type MOS transistor, the second epitaxy material layer is a SiC layer.

In the above fabrication method, the step of removing the exposed surface of the substrate in the second active region for forming the second trench includes a step of removing a part of the protection layer covering the second gate structure and removing a part of the second gate structure. If a MOS device in the second active region is a P-type MOS transistor, the second epitaxy material layer is a SiGe alloy metal layer; and if a MOS device in the first active region is an N-type MOS transistor, the first epitaxy material layer is a SiC layer.

In the present invention, in contrary of using the prior DHF-O₃-DHF clean steps, the pre-clean step, including an oxygen plasma process, is used for effectively cleaning the bottoms of the trenches to be filled with SiGe alloy metal to clean native oxide layers and impurities on the bottom of the trench. The exposedness of the gate structure is prevented and the conventional poly bump disadvantages may be improved. The resultant MOS devices or CMOS devices have good reliability and performance. Further, a short-duration DHF clean step may be performed before or after the oxygen plasma process for further cleaning the native oxide layers or impurities remained on the bottoms of the trenches.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A˜1E show a fabrication method for a MOS device according to a first embodiment of the invention.

FIGS. 2A˜2B show a fabrication method for a MOS device according to a second embodiment of the invention.

FIGS. 3A˜3F show a fabrication method for a CMOS device according to a third embodiment of the invention.

FIGS. 4A˜4C show a fabrication method for a CMOS device according to a fourth embodiment of the invention.

FIGS. 5A˜5C show a fabrication method for a CMOS device according to a fifth embodiment of the invention.

FIGS. 6A˜6B show a fabrication method for a CMOS device according to a sixth embodiment of the invention.

FIGS. 7A˜7C show a fabrication method for a CMOS device according to a seventh embodiment of the invention.

### DESCRIPTION OF EMBODIMENTS

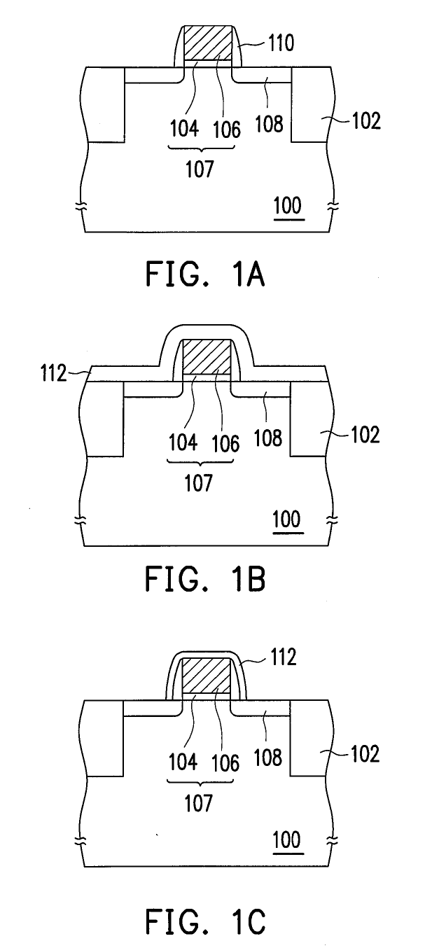

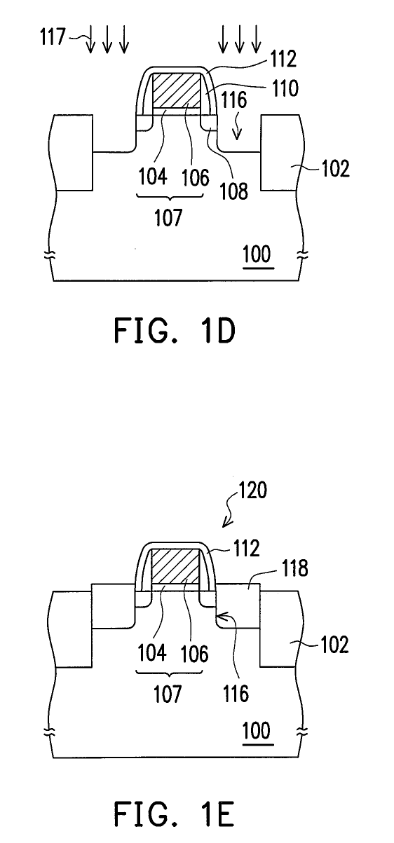

FIGS. 1A˜1E show a fabrication method for a MOS device according to a first embodiment of the invention.

Now, please refer to FIG. 1A. A substrate 100 is provided with an isolation structure 102. The isolation structure 102 may be a shallow trench isolation structure. A gate structure 107 is formed on the substrate 100. The gate structure 107 includes a gate dielectric layer 104 and a gate conductor layer 106. The formation of the gate structure 107 includes, for example but not limited with, the steps of sequentially forming a silica layer (not shown) and a doped a poly-Si layer (not shown) on the substrate 100. Then, the doped poly-Si layer is defined by a mask pattern for forming the gate conductor layer 106. Then, via using the gate conductor layer 106 as a mask pattern, a part of the silica layer is etched for forming the gate dielectric layer 104. Then, lightly-doped drain (LDD) regions 108 are formed at the two sides of the gate structure 107 in the substrate 100. The LDD regions 108 are formed by example, an ion-implant process. Then, spacer walls 110 are formed on the sidewalls of the gate structure 107. The spacer walls 110 are formed by example, forming a spacer material layer (not shown) on the substrate 100 and then performing an anisotropic etching for removing a part of the spacer material layer to form the spacer walls 110.

Now, please refer to FIG. 1B. A protection layer 112 is formed to cover the gate structure 107, the LDD regions 108 and the spacer walls 110. The protection layer 112 is made of for example, an oxide layer by a chemical vapor deposition (CVD).

Now, please refer to FIG. 1C. An anisotropic etching is used for etching a the protection layer 112 to reserve parts of the protection layer 112 on the gate structure and the spacer walls 110 but expose a part of the surface of the substrate 100.

Now, please refer to FIG. 1D. The expose surface of the substrate 100 is removed for forming trenches 116 in the substrate 100. In the subsequent steps, epitaxy material is filled into the trenches 116 for forming source/drain regions.

Before the epitaxy material is filled, a pre-clean step 117 is performed on the bottoms of the trenches 116 in the substrate 100. The pre-clean step 117 includes an oxygen plasma process for cleaning the native oxide layers or impurities remained on the bottoms of the trenches 116 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

Further, the pre-clean step 117 includes a DHF clean step first and then an oxygen plasma process for further cleaning the native oxide layers or impurities remained on the bottoms of the trenches 116. Or, the pre-clean step 117 includes an oxygen plasma process first and then a DHF clean step for cleaning the native oxide layers or impurities remained on the bottoms of the trenches 116. In the first embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 117, a pre-bake step may be used for further cleaning the trenches.

Now, please refer to FIG. 1E, an epitaxy material layer 118 is formed in the trenches 116 and a MOS device 120 is made. The MOS device 120 at least includes the gate structure 107, the LDD regions 108, the spacer walls 110 and the epitaxy material layer 118.

The MOS device 120 may be a P-type MOS transistor and the epitaxy material layer 118 is a SiGe layer made by a selective epitaxial growth (SEG). The method for forming the epitaxy material layer 118 can be, for example but not limited to, an in-situ implantation process with implanting Boron (B) ions. Or, another method for forming the epitaxy material layer 118 can be, for example but not limited to, after a SiGe alloy metal layer is formed, Boron (B) ions are implanted into the SiGe alloy metal layer. The MOS device 120 may be an N-type MOS transistor and the epitaxy material layer 118 is a SiC layer.

In the embodiment, the pre-clean step includes an oxygen plasma process, so exposedness of the gate structure caused by the prior DHF-O₃-DHF clean step may be prevented. In other words, the pre-clean step in the embodiment effectively cleans the bottom surface in the trenches and the conventional poly bump disadvantages may be prevented. So, the resultant MOS device has good reliability and performance.

In the embodiment, a short-duration DHF clean step may be performed before or after the oxygen plasma process for further cleaning the native oxide layers or impurities remained on the bottoms of the trenches.

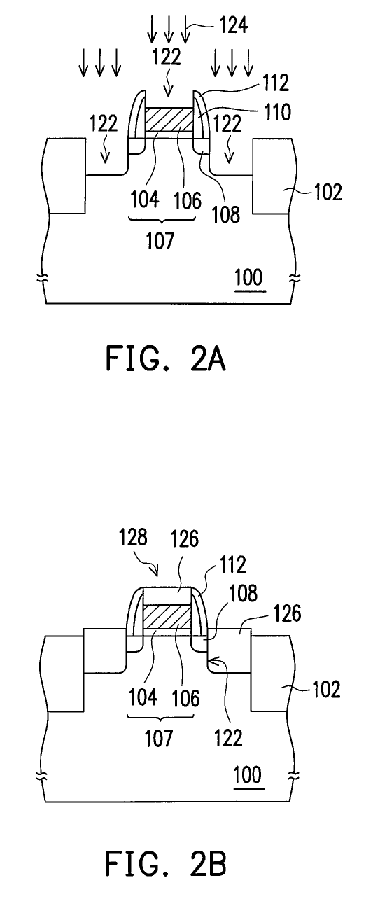

Now, please refer to FIGS. 2A˜2B which show a fabrication method for a MOS device according to a second embodiment of the invention. FIG. 2A shows the steps after FIG. 1C. The similar or the same reference numbers are used in the FIGS. 1A˜1C and FIGS. 2A˜2B and the description to refer to the same or like parts.

Now, please refer to FIG. 2A, the exposed part of the substrate 100 is removed, and the protection layer 112 covering the gate structure 107 and a part of the gate structure 107 underlying are also removed to form trenches 122. A pre-clean step 124 is performed on the trenches 122. The pre-clean step 124 includes an oxygen plasma process for cleaning the native oxide layers or impurities remained on the bottoms of the trenches 122 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 124 includes a DHF clean step first and then an oxygen plasma process for further cleaning the native oxide layers or impurities remained on the bottoms of the trenches 122. Or the pre-clean step 124 includes an oxygen plasma process first and then a DHF clean step for further cleaning the native oxide layers or impurities remained on the bottoms of the trenches 122. In the second embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 124, a pre-bake step may be used for further cleaning the trenches 122.

Now, please refer to FIG. 2B, an epitaxy material layer 126 is formed in the trenches 122 and a MOS device 128 is made. The MOS device 128 at least includes the gate structure 107, the LDD regions 108, the spacer walls 110 and the epitaxy material layer 126. The MOS device 128 is a P-type MOS transistor and the epitaxy material layer 126 is a SiGe layer made by a selective epitaxial growth (SEG). Besides, the epitaxy material layer 126 may be formed by in-situ Boron (B) doping. Or, after a SiGe alloy metal layer is formed, Boron (B) is ion-implanted into the SiGe alloy metal layer to form the epitaxy material layer 126.

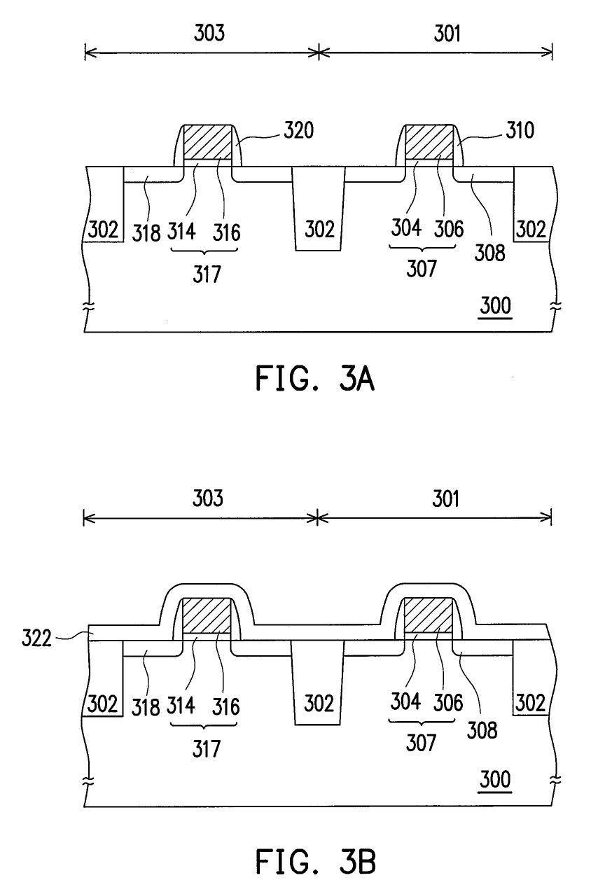

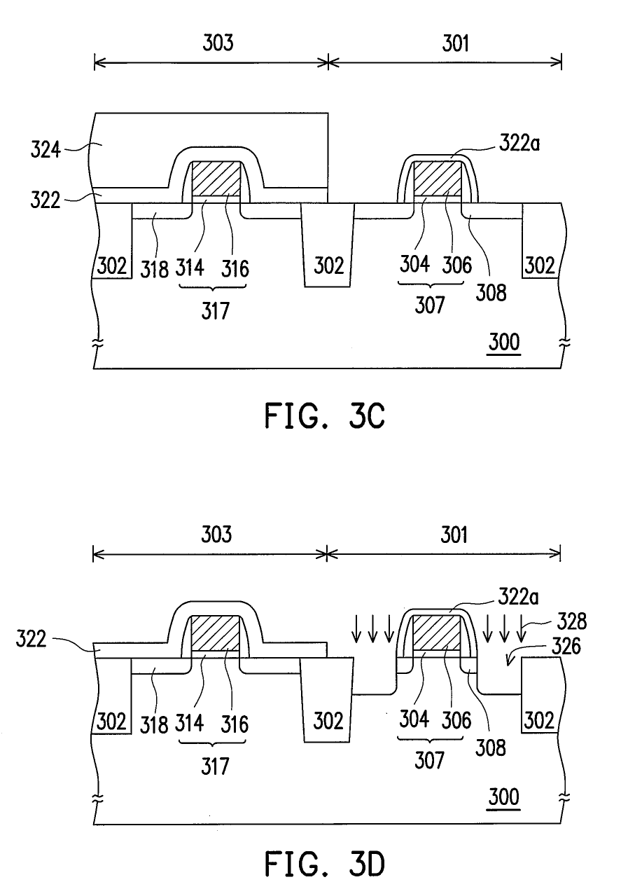

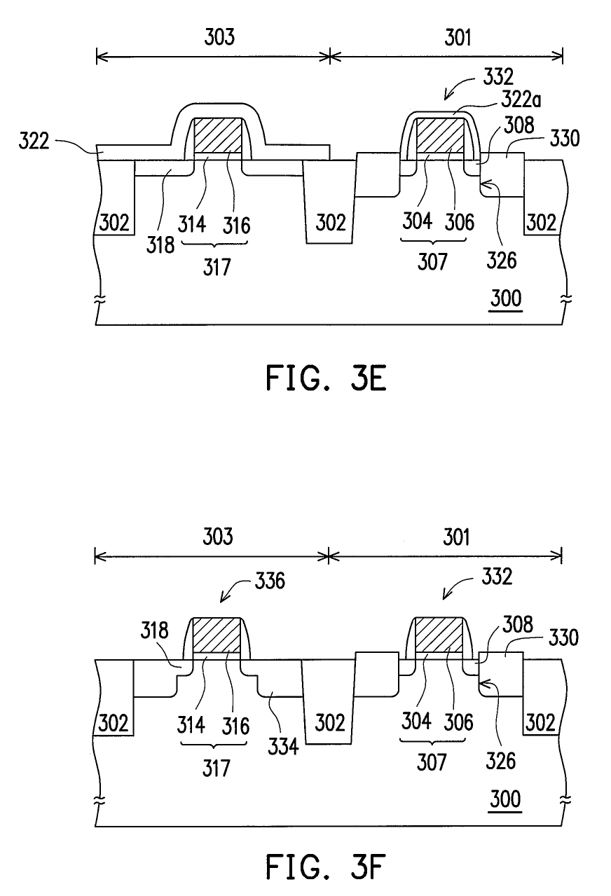

FIGS. 3A˜3F show a fabrication method for a CMOS device according to a third embodiment of the invention.

Now, please refer to FIG. 3A. A substrate 300 is provided with first and second active regions 301 and 303. The first and second active regions 301 and 303 are isolated from each other by an isolation structure 302. The isolation structure 302 maybe a shallow trench isolation structure.

Then, gate structures 307 and 317 are formed on the first and second active regions 301 and 303 in the substrate 300. The gate structure 307 includes a gate dielectric layer 304 and a gate conductor layer 306. The gate structure 317 includes a gate dielectric layer 314 and a gate conductor layer 316. The formation of the gate structure 307 includes, for example but not limited with, the steps of sequentially forming a silica layer (not shown) and a doped a poly-Si layer (not shown) on the substrate 300. Then, the doped poly-Si layer is defined by a mask pattern for forming the gate conductor layer 306. Then, via using the gate conductor layer 306 as a mask pattern, a part of the silica layer is etched for forming the gate dielectric layer 304. The formation of the gate structure 317 includes, for example but not limited with, the steps of sequentially forming another silica layer (not shown) and another doped a poly-Si layer (not shown) on the substrate 300. Then, the doped poly-Si layer is defined by a mask pattern for forming the gate conductor layer 316. Then, via using the gate conductor layer 316 as a mask pattern, a part of the silica layer is etched for forming the gate dielectric layer 314.

Then, lightly-doped drain (LDD) regions 308 and 318 are formed near the two sides of the gate structures 307 and 317 in the substrate 300. The LDD regions 308 and 318 are formed by example, an ion-implant process. Then, spacer walls 310 and 320 are formed on the sidewalls of the gate structures 307 and 317. The spacer walls 310 are formed by example, forming a spacer material layer (not shown) on the substrate 300 and then performing an anisotropic etching for removing a part of the spacer material layer to form the spacer walls 310. Similarly, the spacer walls 320 are formed by example, forming a spacer material layer (not shown) on the substrate 300 and then performing an anisotropic etching for removing a part of the spacer material layer to form the spacer walls 320.

Now, please refer to FIG. 3B. A protection layer 322 is formed on the substrate 300 to cover the whole substrate 300. The protection layer 322 is made of for example, an oxide layer by a chemical vapor deposition.

Now, please refer to FIG. 3C. A photoresist layer 324 is formed to cover the second active region 303 of the substrate 300. Then, by defining the photoresist layer 324 as a mask pattern, a part of the protection layer 322 on the first active region 303 is removed to expose the surface of the substrate 300 in the first active region 301. Another protection layer 322a is formed on the gate structure 307 and the spacer walls 310.

Now, please refer to FIG. 3D. The photoresist layer 324 is removed. Then, the exposed surface of the substrate 300 in the first active region 301 is removed for forming trenches 326 in the substrate 300.

Then, a pre-clean step 328 is performed on the bottoms of the trenches 326 in the substrate 300. The pre-clean step 328 includes an oxygen plasma process for cleaning the native oxide layers or impurities remained on the bottoms of the trenches 326 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 328 includes a DHF clean step first and then an oxygen plasma process for cleaning the native oxide layers or impurities remained on the bottoms of the trenches 326. Or, the pre-clean step 328 includes an oxygen plasma process first and then a DHF clean step for cleaning the native oxide layers or impurities remained on the bottoms of the trenches 326. In the third embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 328, a pre-bake step may be used for further cleaning the trenches 326.

Now, please refer to FIG. 3E. An epitaxy material layer 330 is formed in the trenches 328 and a MOS device 332 in the first active region 301 is made. The MOS device 332 at least includes the gate structure 307, the LDD regions 308, the spacer walls 310 and the epitaxy material layer 330.

Now, please refer to FIG. 3F. The protection layers 322 and 322a are removed. Then heavily-doped regions 334 are formed near the sides of the spacer walls 320 in the second active region 303 in the substrate 300 and a MOS device 336 in the second active region 303 is made. The MOS device 336 at least includes the gate structure 317, the LDD regions 318, the spacer walls 320 and heavily-doped regions 334. The MOS device 332 in the first active region 301 and the MOS device 336 in the second active region 303 constitute a CMOS device.

If the MOS device 332 in the first active region 301 is a P-type MOS transistor and the MOS device 336 in the second active region 303 is an N-type MOS transistor, the epitaxy material layer 330 is for example a SiGe alloy metal layer and the heavily-doped regions 334 are doped by n-type dopant.

If the MOS device 332 in the first active region 301 is an N-type MOS transistor and the MOS device 336 in the second active region 303 is a P-type MOS transistor, the epitaxy material layer 330 is for example a SiC layer and the heavily-doped regions 334 are doped by p-type dopant.

In the third embodiment, the pre-clean step, including an oxygen plasma process, is used for cleaning the bottom surface of the trenches to be filled with the epitaxy material layer. In the third embodiment, the pre-clean step effectively cleans the bottom surface in the trenches and the conventional poly bump disadvantages (i.e. the exposedness of the gate structure) may be prevented. So, the resultant CMOS device has good reliability and performance.

In pre-clean step of the third embodiment, a short-duration DHF clean step may be performed before or after the oxygen plasma process for further cleaning the native oxide layers or impurities remained on the bottoms of the trenches.

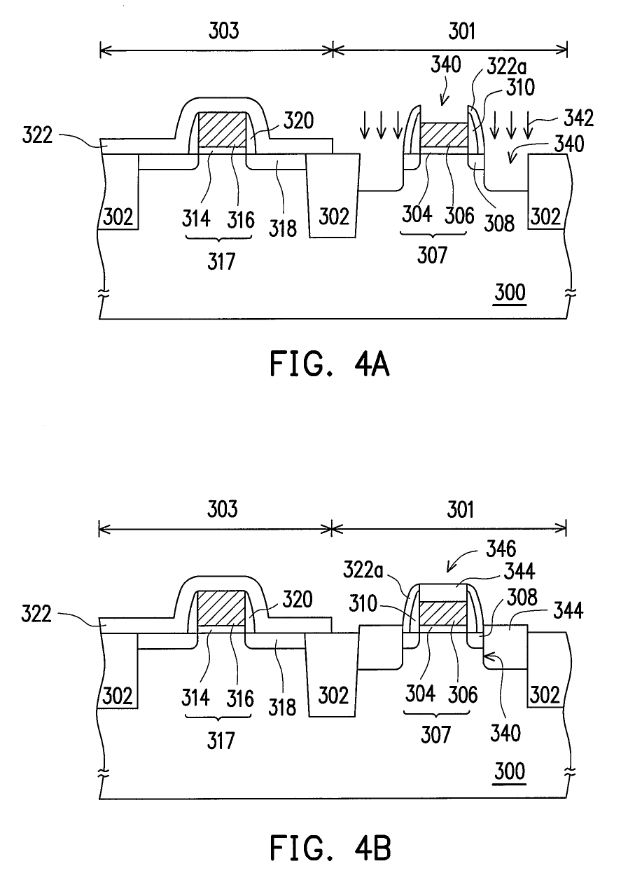

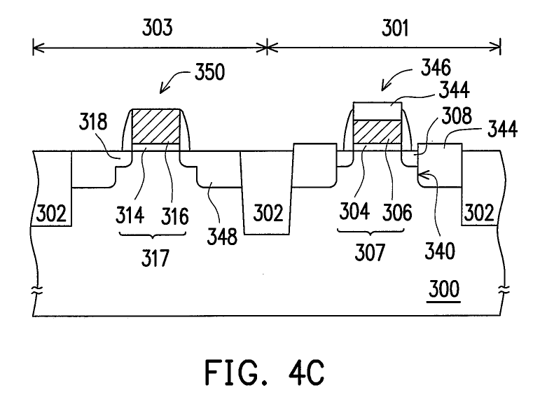

Now, please refer to FIGS. 4A˜4C which show a fabrication method for a CMOS device according to a fourth embodiment of the invention. FIG. 4A shows the steps after FIG. 3C. The similar or the same reference numbers are used in the FIGS. 4A˜4C and FIGS. 3A˜3C and the description to refer to the same or like parts.

Now, please refer to FIG. 4A. The photoresist layer 324 is removed. Then, the exposed surface of the substrate 300 in the first active region 301 is removed, and the protection layer 322a covering the gate structure 307 and a part of underlying gate structure 307 are removed for forming trenches 340.

Then, a pre-clean step 342 is performed on the bottoms of the trenches 340 in the substrate 300. The pre-clean step 342 includes an oxygen plasma process for cleaning the native oxide layers or impurities remained on the bottoms of the trenches 340 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 342 may include a DHF clean step first and then an oxygen plasma process for further cleaning the native oxide layers or impurities remained on the bottoms of the trenches 340. Or, the pre-clean step 342 may include an oxygen plasma process first and then a DHF clean step for cleaning the native oxide layers or impurities remained on the bottoms of the trenches 342. In the fourth embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Even, after the pre-clean step 342, a pre-bake step may be used for further cleaning the trenches 340.

Now, please refer to FIG. 4B. An epitaxy material layer 344 is formed in the trenches 340 and a MOS device 346 in the first active region 301 is made. The MOS device 346 at least includes the gate structure 307, the LDD regions 308, the spacer walls 310 and the epitaxy material layer 344.

Now, please refer to FIG. 4C. The protection layers 322 and 322a are removed. Then heavily-doped regions 348 are formed near the sides of the spacer wall 320 in the second active region 303 in the substrate 300 and a MOS device 350 in the second active region 303 is made. The MOS device 350 at least includes the gate structure 317, the LDD regions 318, the spacer walls 320 and heavily-doped regions 348. The MOS device 346 in the first active region 301 and the MOS device 350 in the second active region 303 constitute a CMOS device.

If the MOS device 346 in the first active region 301 is a P-type MOS transistor and the MOS device 350 in the second active region 303 is an N-type MOS transistor, the epitaxy material layer 344 is for example a SiGe alloy metal layer and the heavily-doped regions 348 are doped by n-type dopant.

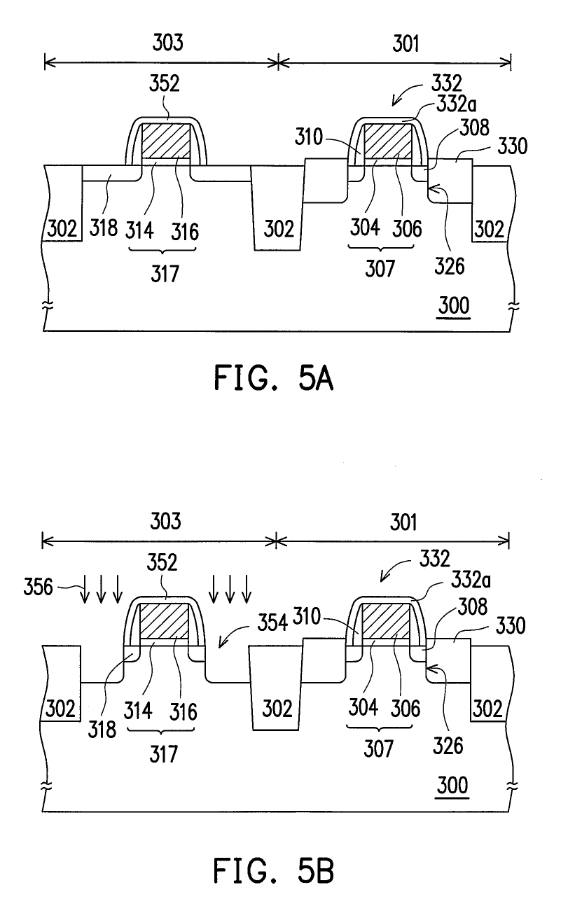

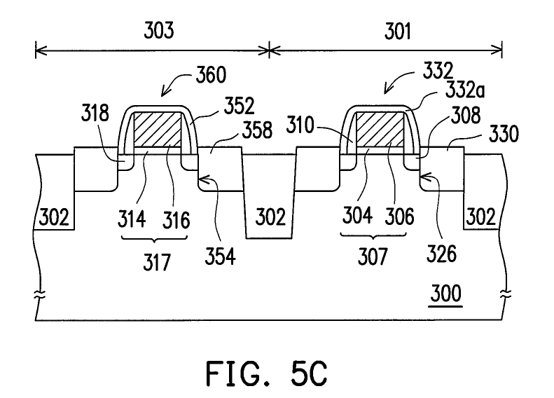

Now, please refer to FIGS. 5A˜5C which show a fabrication method for a CMOS device according to a fifth embodiment of the invention. FIG. 5A shows the steps after FIG. 3E. The similar or the same reference numbers are used in the FIGS. 5A˜5C and FIGS. 3A˜3E and the description to refer to the same or like parts.

Now, please refer to FIG. 5A. A part of the protection layer 322 in the second active region 303 is removed to expose a part of the substrate 300 in the second active region 303. Then, a protection layer 352 is formed. The protection layer 352 covers the gate structure 317 and the spacer walls 320.

Now, please refer to FIG. 5B. The exposed surface of the substrate 300 in the second active region 303 is removed for forming trenches 354. Then, a pre-clean step 356 is performed on the bottoms of the trenches 354 in the substrate 300. The pre-clean step 356 includes an oxygen plasma process for cleaning the native oxide layers or impurities remained on the bottoms of the trenches 354 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 356 may include a DHF clean step first and then an oxygen plasma process for further cleaning the native oxide layers or impurities remained on the bottoms of the trenches 354. Or, the pre-clean step 356 may include an oxygen plasma process first and then a DHF clean step for cleaning the native oxide layers or impurities remained on the bottoms of the trenches 354. In the fifth embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 356, a pre-bake step may be used for further cleaning the trenches 354.

Now, please refer to FIG. 5C. An epitaxy material layer 358 is formed in the trenches 354 and a MOS device 360 in the second active region 303 is made. The MOS device 360 at least includes the gate structure 317, the LDD regions 318, the spacer walls 320 and the epitaxy material layer 358. The MOS device 332 in the first active region 301 and the MOS device 360 in the second active region 303 constitute a CMOS device.

If the MOS device 332 in the first active region 301 is a P-type MOS transistor and the MOS device 360 in the second active region 303 is an N-type MOS transistor, the epitaxy material layers 330 and 385 are a SiGe alloy metal layer and a SiC layer respectively. Or, if the MOS device 332 in the first active region 301 is an N-type MOS transistor and the MOS device 360 in the second active region 303 is a P-type MOS transistor, the epitaxy material layers 330 and 385 are a SiC layer and a SiGe alloy metal layer respectively.

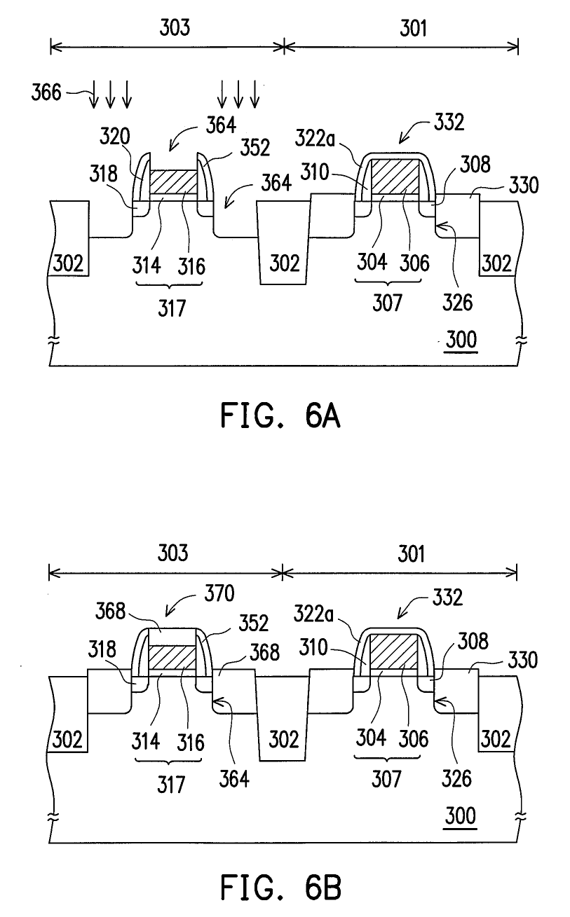

Now, please refer to FIGS. 6A˜6B which show a fabrication method for a CMOS device according to a sixth embodiment of the invention. FIG. 6A shows the steps after FIG. 5A. The similar or the same reference numbers are used in the FIGS. 6A˜6B and FIG. 5A and the description to refer to the same or like parts.

Now, please refer to FIG. 6A. The exposed substrate 300 in the second active region 303 is removed, and the protection layer 352 covering the gate structure 317 and a part of the underlying gate structure 317 are removed for forming trenches 364. Then, a pre-clean step 366 is performed on the bottoms of the trenches 364 in the substrate 300. The pre-clean step 366 includes an oxygen plasma process for cleaning the native oxide layers or impurities remained on the bottoms of the trenches 364 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 366 may include a DHF clean step first and then an oxygen plasma process for further cleaning the native oxide layers or impurities remained on the bottoms of the trenches 364. Or, the pre-clean step 366 may include an oxygen plasma process first and then a DHF clean step for cleaning the native oxide layers or impurities remained on the bottoms of the trenches 364. In the sixth embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 366, a pre-bake step may be used for further cleaning the trenches 364.

Now, please refer to FIG. 6B. An epitaxy material layer 368 is formed in the trenches 364 and a MOS device 370 in the second active region 303 is made. The MOS device 370 at least includes the gate structure 317, the LDD regions 318, the spacer walls 320 and the epitaxy material layer 368. The MOS device 332 in the first active region 301 and the MOS device 370 in the second active region 303 constitute a CMOS device.

If the MOS device 332 in the first active region 301 is an N-type MOS transistor and the MOS device 370 in the second active region 303 is a P-type MOS transistor, the epitaxy material layers 330 and 368 are a SiC layer and a SiGe alloy metal layer respectively.

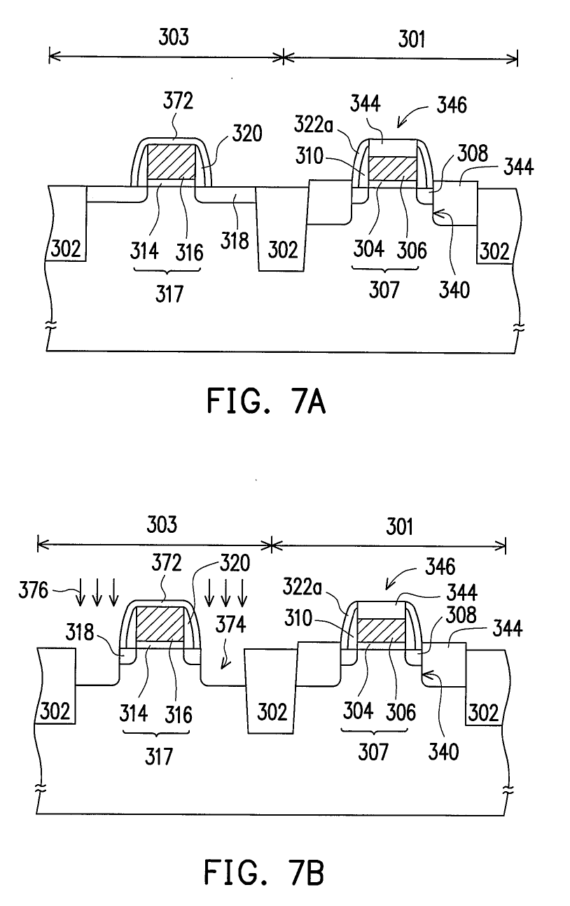

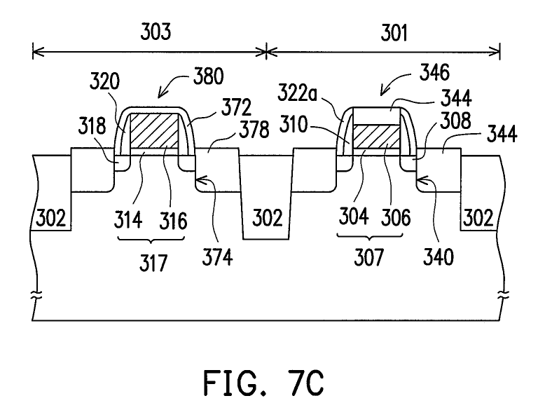

Now, please refer to FIGS. 7A˜7C which show a fabrication method for a CMOS device according to a seventh embodiment of the invention. FIG. 7A shows the steps after FIG. 4B. The similar or the same reference numbers are used in the FIGS. 7A˜7C and FIGS. 4A˜4B and the description to refer to the same or like parts.

Now, please refer to FIG. 7A. A part of the protection layer 322 in the second active region 303 is removed for exposing a part of the substrate 300 in the second active region 303. A protection layer 372 is formed. The protection layer 372 covers the gate structure 317 and the spacer walls 320.

Now, please refer to FIG. 7B. The exposed structure 300 in the second active region 303 is removed for forming trenches 374. Then, a pre-clean step 376 is performed on the bottoms of the trenches 374 in the substrate 300. The pre-clean step 376 includes an oxygen plasma process for cleaning the native oxide layers or impurities remained on the bottoms of the trenches 374 by oxygen plasma. The oxygen-based gas source in the oxygen plasma process includes O₂, NO or N₂O. Or, in the oxygen plasma process, a secondary gas may be used. The secondary gas source includes H₂, NH₃ or D₂. In the oxygen plasma process, the power condition is between 10 W˜2000 W and the temperature condition is between 300° C.˜500° C.

The pre-clean step 376 may include a DHF clean step first and then an oxygen plasma process for further cleaning the native oxide layers or impurities remained on the bottoms of the trenches 374. Or, the pre-clean step 376 may include an oxygen plasma process first and then a DHF clean step for cleaning the native oxide layers or impurities remained on the bottoms of the trenches 374. In the seventh embodiment, the concentration of the HF solution used in the DHF clean step is for example, a volume percent of 0.5. The duration for the DHF clean step is between 60 seconds˜180 seconds, a temperature condition for the DHF clean step is room temperature (25 degree C.).

Further, after the pre-clean step 376, a pre-bake step may be used for further cleaning the trenches 374.

Now, please refer to FIG. 7C. An epitaxy material layer 378 is formed in the trenches 374 and a MOS device 380 in the second active region 303 is made. The MOS device 380 at least includes the gate structure 317, the LDD regions 318, the spacer walls 320 and the epitaxy material layer 378. The MOS device 346 in the first active region 301 and the MOS device 380 in the second active region 303 constitute a CMOS device.

If the MOS device 346 in the first active region 301 is a P-type MOS transistor and the MOS device 380 in the second active region 303 is an N-type MOS transistor, the epitaxy material layers 344 and 378 are a SiGe alloy metal layer and a SiC layer respectively.

As discussed above, in the embodiments of the present invention, the pre-clean step includes an oxygen plasma process for effectively cleaning the bottoms of the trenches and preventing the exposedness of the gate structure. So, the conventional poly bump disadvantages may be prevented. The resultant MOS devices or CMOS devices have good reliability and performance. Further, a short-duration DHF clean step may be performed before or after the oxygen plasma process for further cleaning the native oxide layers or impurities remained on the bottoms of the trenches.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method for fabricating a MOS device, comprising:
providing a substrate with a gate structure formed on the substrate, a lightly-doped drain region formed near sides of the gate structure in the substrate and a spacer wall formed on sidewalls of the gate structure and covering a part of the lightly-doped drain region;
forming a protection layer on the substrate for covering the gate structure, the lightly-doped drain region and the spacer wall;
performing an anisotropic etching for removing a part of the protection layer, reserving another part of the protection layer on the gate structure and the spacer wall, and exposing a part of the surface of the substrate;
removing the exposed surface of the substrate for forming a trench in the substrate;
performing a pre-clean step on the bottom of the trench, the pre-clean step including an oxygen plasma process; and
forming an epitaxy material layer in the trench.

2. The method of claim 1, wherein the oxygen plasma process has a power condition between 10 W˜2000 W.

3. The method of claim 1, wherein the oxygen plasma process has a temperature condition between 300° C˜500° C.

4. The method of claim 1, wherein a gas source used in the oxygen plasma process includes O₂, NO or N₂O.

5. The method of claim 4, wherein a secondary gas source used in the oxygen plasma process includes H₂, NH₃ or D₂.

6. The method of claim 1, wherein the pre-clean step further includes a DHF clean step.

7. The method of claim 6, wherein a duration for the DHF clean step is between 60 seconds˜180 seconds, a temperature condition for the DHF clean step is room temperature (25 degree C.), and a concentration of a HF solution used in the DHF clean step is a volume percent of 0.5.

8. The method of claim 1, further comprising a pre-bake step after the pre-clean step.

9. The method of claim 1, wherein if the MOS: device is a P-type MOS transistor, the epitaxy material layer is a SiGe alloy metal layer.

10. The method of claim 1, wherein if the MOS device is an N-type MOS transistor, the epitaxy material layer is a SiC layer.

11. A method for fabricating a MOS device, comprising:
providing a substrate with a gate structure formed on the substrate, a lightly-doped drain region formed near sides of the gate structure in the substrate and a spacer wall formed on sidewalls of the gate structure and covering a part of the lightly-doped drain region;
forming a protection layer on the substrate for covering the gate structure, the lightly-doped drain region and the spacer wall;
performing an anisotropic etching for removing a part of the protection layer, reserving another part of the protection layer on the gate structure and the spacer wall, and exposing a part of the surface of the substrate;
removing the exposed surface of the substrate and removing the another part of the protection layer on the gate structure and a part of the gate structure, for forming a trench in the substrate;
performing a pre-clean step on the bottom of the trench, the pre-clean step including an oxygen plasma process; and
forming an epitaxy material layer in the trench.

12. The method of claim 11, wherein the oxygen plasma process has a power condition between 10 W˜2000 W.

13. The method of claim 11, wherein the oxygen plasma process has a temperature condition between 300° C.˜500° C.

14. The method of claim 11, wherein a gas source used in the oxygen plasma process includes O₂, NO or N₂O.

15. The method of claim 14, wherein a secondary gas source used in the oxygen plasma process includes H₂, NH₃ or D₂.

16. The method of claim 11, wherein the pre-clean step further includes a DHF clean step.

17. The method of claim 16, wherein a duration for the DHF clean step is between 60 seconds˜180 seconds, a temperature condition for the DHF clean step is room temperature (25 degree C.), and a concentration of a HF solution used in the DHF clean step is a volume percent of 0.5.

18. The method of claim 11, further comprising a pre-bake step after the pre-clean step.

19. The method of claim 11, wherein if the MOS device is a P-type MOS transistor, the epitaxy material layer is a SiGe alloy metal layer.

20. A method for fabricating a CMOS device, comprising:
providing a substrate with first and second active regions, the first and second active regions being isolated by an isolation structure, a first gate structure formed in the first active region of the substrate, a first lightly-doped drain region formed near sides of the first gate structure in the substrate and a first spacer wall formed on sidewalls of the first gate structure and covering a part of the first lightly-doped drain region; a second gate structure formed in the second active region of the substrate, a second lightly-doped drain region formed near sides of the second gate structure in the substrate and a second spacer wall formed on sidewalls of the second gate structure and covering a part of the second lightly-doped drain region;
forming a protection layer on the substrate for covering the substrate;
removing a part of the protection layer in the first active region, reserving another part of the protection layer on the first gate structure and the first spacer wall, and exposing a part of the surface of the substrate in the first active region;
removing the exposed surface of the substrate in the first active region for forming a trench;
performing a pre-clean step on the bottom of the trench, the pre-clean step including an oxygen plasma process;
forming an epitaxy material layer in the trench;
removing the protection layer; and
forming a heavily doped region near sides of the second spacer wall in the second active region of the substrate.

21. The method of claim 20, wherein the oxygen plasma process has a power condition between 10 W˜2000 W.

22. The method of claim 20, wherein the oxygen plasma process has a temperature condition between 300° C.˜500° C.

23. The method of claim 20, wherein a gas source used in the oxygen plasma process includes O₂, NO or N₂O.

24. The method of claim 23, wherein a secondary gas source used in the oxygen plasma process includes H₂, NH₃ or D₂.

25. The method of claim 20, wherein the pre-clean step further includes a DHF clean step.

26. The method of claim 25, wherein a duration for the DHF clean step is between 60 seconds˜180 seconds, a temperature condition for the DHF clean step is room temperature (25 degree C.), and a concentration of a HF solution used in the DHF clean step is a volume percent of 0.5.

27. The method of claim 20, further comprising a pre-bake step after the pre-clean step.

28. The method of claim 20, wherein if a MOS device in the first active region is a P-type MOS transistor, the epitaxy material layer is a SiGe alloy metal layer.

29. The method of claim 20, wherein if a MOS device in the first active region is an N-type MOS transistor, the epitaxy material layer is a SiC layer.

30. The method of claim 20, wherein the step of removing the exposed surface of the substrate in the first active region for forming the trench includes a step of removing a part of the protection layer covering the first gate structure and removing a part of the first gate structure.

31. The method of claim 30, wherein if a MOS device in the first active region is a P-type MOS transistor, the epitaxy material layer is a SiGe alloy metal layer.

32. A method for fabricating a CMOS device, comprising:
providing a substrate with first and second active regions, the first and second active regions being isolated by an isolation structure, a first gate structure formed in the first active region of the substrate, a first lightly-doped drain region formed near sides of the first gate structure in the substrate and a first spacer wall formed on sidewalls of the first gate structure and covering a part of the first lightly-doped drain region; a second gate structure formed in the second active region of the substrate, a second lightly-doped drain region formed near sides of the second gate structure in the substrate and a second spacer wall formed on sidewalls of the second gate structure and covering a part of the second lightly-doped drain region;
forming a protection layer on the substrate for covering the substrate;
removing a part of the protection layer in the first active region, reserving another part of the protection layer on the first gate structure and the first spacer wall, and exposing a part of the surface of the substrate in the first active region;
removing the exposed surface of the substrate in the first active region for forming a first trench;
performing a pre-clean step on the bottom of the first trench, the pre-clean step including an oxygen plasma process;
forming a first epitaxy material layer in the first trench;
removing a part of the protection layer in the second active region, reserving another part of the protection layer on the second gate structure and the second spacer wall, and exposing a part of the surface of the substrate in the second active region;
removing the exposed surface of the substrate in the second active region for forming a second trench;
performing the pre-clean step on the bottom of the second trench; and
forming a second epitaxy material layer in the second trench.

33. The method of claim 32, wherein the oxygen plasma process has a power condition between 10 W˜2000 W.

34. The method of claim 32, wherein the oxygen plasma process has a temperature condition between 300° C.˜500° C.

35. The method of claim 32, wherein a gas source used in the oxygen plasma process includes O₂, NO or N₂O.

36. The method of claim 35, wherein a secondary gas source used in the oxygen plasma process includes H₂, NH₃ or D₂.

37. The method of claim 32, wherein the pre-clean step further includes a DHF clean step.

38. The method of claim 37, wherein a duration for the DHF clean step is between 60 seconds˜180 seconds, a temperature condition for the DHF clean step is room temperature (25 degree C.), and a concentration of a HF solution used in the DHF clean step is a volume percent of 0.5.

39. The method of claim 32, further comprising a pre-bake step after the pre-clean step.

40. The method of claim 32, wherein if a MOS device in the first active region is a P-type MOS transistor, the first epitaxy material layer is a SiGe alloy metal layer; and if a MOS device in the second active region is an N-type MOS transistor, the second epitaxy material layer is a SiC layer.

41. The method of claim 32, wherein if a MOS device in the first active region is an N-type MOS transistor, the first epitaxy material layer is a SiC layer; and if a MOS device in the second active region is a P-type MOS transistor, the second epitaxy material layer is a SiGe alloy metal layer.

42. The method of claim 32, wherein the step of removing the exposed surface of the substrate in the first active region for forming the first trench includes a step of removing a part of the protection layer covering the first gate structure and removing a part of the first gate structure.

43. The method of claim 42, wherein if a MOS device in the first active region is a P-type MOS transistor, the first epitaxy material layer is a SiGe alloy metal layer; and if a MOS device in the second active region is an N-type MOS transistor, the second epitaxy material layer is a SiC layer.

44. The method of claim 32, wherein the step of removing the exposed surface of the substrate in the second active region for forming the second trench includes a step of removing a part of the protection layer covering the second gate structure and removing a part of the second gate structure.

45. The method of claim 44, wherein if a MOS device in the second active region is a P-type MOS transistor, the second epitaxy material layer is a SiGe alloy metal layer; and if a MOS device in the first active region is an N-type MOS transistor, the first epitaxy material layer is a SiC layer.
